(19) United States
(12) Patent Application Publication
(10) Pub. No.: US 2023/0352451 A1
(43) Pub. Date: Nov. 2, 2023

(54) THREE-DIMENSIONAL FAN-OUT MEMORY POP STRUCTURE AND PACKAGING METHOD THEREOF

(71) Applicant: SJ Semiconductor(Jiangyin) Corporation, Jiangyin City (CN)

(72) Inventors: Yenheng Chen, Jiangin City (CN); Chengchung Lin, Jiangyin City (CN)

(21) Appl. No.: 18/139,748

(22) Filed: Apr. 26, 2023

(30) Foreign Application Priority Data
Apr. 29, 2022 (CN) 202210475755.1

(51) Int. Cl. H01L 25/065; H01L 21/56; H01L 23/31; H01L 23/48; H01L 23/528; H01L 23/00

(52) U.S. Cl. CPC H01L 25/0657; H01L 21/565; H01L 23/3128; H01L 23/481; H01L 23/5283; H01L 24/13; H01L 24/23; H01L 2224/13008; H01L 2224/211; H10B 80/00

(57) ABSTRACT

A POP structure of a three-dimensional fan-out memory and a packaging method are disclosed. The POP structure includes a first package unit of three-dimensional fan-out memory device and a system-in-package (SiP) package unit of the two-dimensional fan-out peripheral circuit. The first package unit includes: memory chips laminated in a stepped configuration; first metal connection pillars connected to the memory chips; a first encapsulating layer; a first rewiring layer; and first metal bumps formed on the first rewiring layer. The SiP package unit includes: a second rewiring layer; one peripheral circuit chip; a third rewiring layer bonded to the peripheral circuit chip; second metal connection pillars; a second encapsulating layer on the peripheral circuit chip and the second metal connection pillars; and second metal bumps on the second rewiring layer. Attaching the first package unit and the SiP package unit by bonding first metal bumps to the third rewiring layer.

### CROSS REFERENCE TO RELATED APPLICATION

The present application claims the benefit of priority to Chinese Patent Application No. CN 202210475755.1, entitled “THREE-DIMENSIONAL FAN-OUT MEMORY POP STRUCTURE AND PACKAGING METHOD THEREOF”, filed with CNIPA on Apr. 29, 2022, the disclosure of which is incorporated herein by reference in its entirety.

### FIELD OF TECHNOLOGY

The present disclosure relates to the technical field of semiconductor packaging, in particular, to a package-on-package (POP) structure of a three-dimensional fan-out memory device and a packaging method thereof.

### BACKGROUND

In traditional substrate manufacturing, the printed circuit boards (PCBs) support electronic components, and also serve as carriers for electrical connecting conduits between electronic components. In batch applications, the number of substrate layers is usually no more than 12 layers. The more chip I/O connections are on the substrates, the more substrate layers will be needed, and the higher the overall cost will be. The production process can also have certain limits. Currently, the line width/line spacing has a minimum at set 20 μm/20 μm, but more frequently 50 μm/50 μm applies. As the front-end chip manufacturing is capable at an increasingly higher integration level in functions, the current substrate technology will no longer be able to support the integrating requirements of the front-end chip manufacturing. Therefore, various advanced packaging techniques have been developed, such as the 2.5D & fan-out wafer level advanced packaging technology. However, these technologies are more expensive and take longer to apply than substrate manufacturing techniques.

### SUMMARY

The present disclosure provides a package-on-package (POP) structure, which includes: a first package unit, including a three-dimensional fan-out memory device; and a system-in-package (SiP) package unit, including a two-dimensional fan-out peripheral circuit. The first package unit and the SiP package unit are bonded together.

The three-dimensional fan-out memory device includes: at least two memory chips laminated in a stepped configuration, each of the at least two memory chips being provided with one of bonding pads arranged on one step surface of the stepped configuration; first metal connection pillars, each of the first metal connection pillars being formed on and electrically connected to one of the bonding pads; a first encapsulating layer, which encapsulates the at least two memory chips and the first metal connection pillars, top surfaces of the first metal connection pillars being exposed from a first surface of the first encapsulating layer; a first rewiring layer having a first surface and a second surface, the second surface of the first rewiring layer being formed on the first surface of the first encapsulating layer, and the first rewiring layer being electrically connected to the first metal connection pillars; and first metal bumps, formed on the first surface of the first rewiring layer.

The two-dimensional fan-out peripheral circuit includes: a second rewiring layer having a first surface and a second surface; at least one peripheral circuit chip, arranged in two dimensions and electrically connected with the first surface of the second rewiring layer; a third rewiring layer having a first surface and a second surface, the second surface of the third rewiring layer being bonded to the at least one peripheral circuit chip; second metal connection pillars, disposed outside of the at least one peripheral circuit chip, each of the second metal connection pillars having one end electrically connected with the first surface of the second rewiring layer, and another end electrically connected with the second surface of the third rewiring layer; a second encapsulating layer, encapsulating the at least one peripheral circuit chip and the second metal connection pillars, top surfaces of the second metal connection pillars being exposed from a top surface of the second encapsulating layer; and second metal bumps, formed on the second surface of the second rewiring layer.

The first metal bumps are bonded to the first surface of the third rewiring layer to achieve attachment between the first package unit of the three-dimensional fan-out memory device and the SiP package unit of the two-dimensional fan-out peripheral circuit.

The present disclosure further provides a method of packaging a package-on-package (POP) structure, including: forming a first package unit comprising a three-dimensional fan-out memory device; and forming a system-in-package (SiP) package unit comprising a two-dimensional fan-out peripheral circuit.

Forming the first package unit of the three-dimensional fan-out memory device includes: providing at least two memory chips laminated in a stepped configuration, each of the at least two memory chips being provided with one of bonding pads arranged on one of step surfaces of the stepped configuration; forming first metal connection pillars, each of the first metal connection pillars being disposed on and electrically connected to one of the bonding pads; forming a first encapsulating layer which encapsulates the at least two memory chips and the first metal connection pillars, top surfaces of the first metal connection pillars being exposed from a first surface of the first encapsulating layer; forming a first rewiring layer having a first surface and a second surface, the second surface of the first rewiring layer being formed on the first surface of the first encapsulating layer, and the first rewiring layer being electrically connected to the first metal connection pillars; and forming first metal bumps on the first surface of the first rewiring layer.

Forming the SiP package unit of the two-dimensional fan-out peripheral circuit includes: forming a second rewiring layer having a first surface and a second surface; providing at least one peripheral circuit chip, the at least one peripheral circuit chip being arranged in two dimensions and electrically connected with the first surface of the second rewiring layer; forming a third rewiring layer having a first surface and a second surface, the second surface of the third rewiring layer being bonded to the at least one peripheral circuit chip; forming second metal connection pillars, the second metal connection pillars being disposed outside of the at least one peripheral circuit chip, each of the second metal connection pillars having one end electrically connected with the first surface of the second rewiring layer, and another end electrically connected with the second surface of the third rewiring layer; forming a second encapsulating layer which encapsulates the at least one peripheral circuit chip and the second metal connection pillars, top surfaces of the second metal connection pillars being exposed from the second encapsulating layer; and forming second metal bumps, the second metal bumps being disposed on the second surface of the second rewiring layer.

The method of packaging the package-on-package (POP) structure further includes: bonding the first metal bumps to the first surface of the third rewiring layer, to achieve attachment between the first package unit of the three-dimensional fan-out memory device and the SiP package unit of the two-dimensional fan-out peripheral circuit.

As mentioned above, the POP structure of the three-dimensional fan-out memory provided by the present disclosure adopts a fan-out pattern and realizes a package-on-package (POP) structure by multiple rewiring layers in which a three-dimensional fan-out memory package unit and a two-dimensional fan-out peripheral circuit chip SiP package unit are interconnected, thereby obtaining a memory-encapsulated POP structure. In addition, the first metal connection pillars enable the leadout of the memory chip circuit, and TSV holes are not required in the entire package structure for any circuit lead-out, which effectively reduces packaging costs. This eliminates the circuit substrate required for traditional electronic component packaging, enables high-density and high-integration device packaging, and achieves the minimum line width/line spacing reduction to 1.5 μm/1.5 μm. As a result, the process time will be shortened, and efficiency will be increased. Further, the overall thickness dimension of the package structure will be significantly reduced. Finally, this POP structure makes it possible to realize a one-stop packaging process in which a substrate is used to support the back-end-of-line (BEOL) instead of the middle-end-of-line (MEOL).

### BRIEF DESCRIPTION OF THE DRAWINGS

FIG. 1 shows a schematic structural diagram of laminated memory chips in the three-dimensional fan-out memory POP structure according to the present disclosure.

FIG. 2 shows a schematic structural diagram of a memory package unit for a three-dimensional fan-out memory POP structure according to the present disclosure.

FIG. 3 shows a schematic structural diagram of a peripheral circuit chip SiP package unit for a three-dimensional fan-out memory POP structure according to the present disclosure.

FIG. 4 shows a schematic structural diagram of a three-dimensional fan-out memory POP structure integrating with a memory package unit and a peripheral circuit chip SiP package unit according to the present disclosure.

### DESCRIPTION OF REFERENCE NUMERALS

10 Three-dimensional fan-out memory package unit

101 Memory chip

102 Bonding pad

103 First metal connection pillar

104 First encapsulating layer

105 First rewiring layer

106 Dielectric layer for the first, second and third rewiring layers

107 Metal wiring layer for the first, second and third rewiring layers

108 First metal bump

109 First bonding layer

20 Two-dimensional fan-out peripheral circuit chip SiP package unit

201 Second rewiring layer

202 Peripheral circuit chip

203 Third rewiring layer

204 Second encapsulating layer

205 Second metal bump

206 Second metal connection pillar

207 Bottom filler layer

208 Second bonding layer

### DETAILED DESCRIPTION

The embodiments of the present disclosure will be described below. Those skilled in the art can easily understand other advantages and effects of the present disclosure according to contents disclosed by the specification. The present disclosure may also be implemented or applied through other different specific implementation modes. Various modifications or changes may be made to all details in the specification based on different points of view and applications without departing from the spirit of the present disclosure.

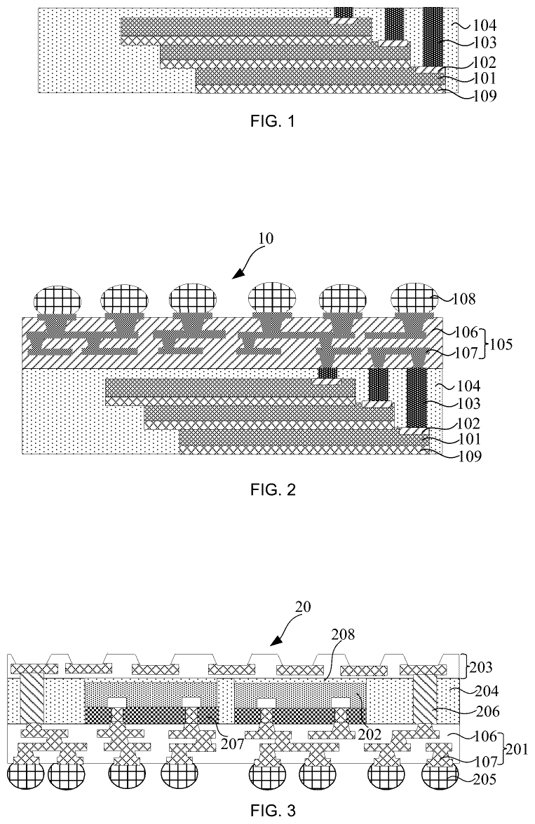

Please refer to FIGS. 1-4. It needs to be stated that the drawings provided in the following embodiments are just used for schematically describing the basic concept of the present disclosure, thus only components related to the present disclosure are illustrated, and these illustrations are not drawn according to the occurring numbers, shapes and sizes of components during actual implementation. The configuration, number and scale of each component during actual implementation thereof may be changed according to actual needs, and the component layout configuration thereof may be more complicated than what is illustrated.

### Embodiment 1

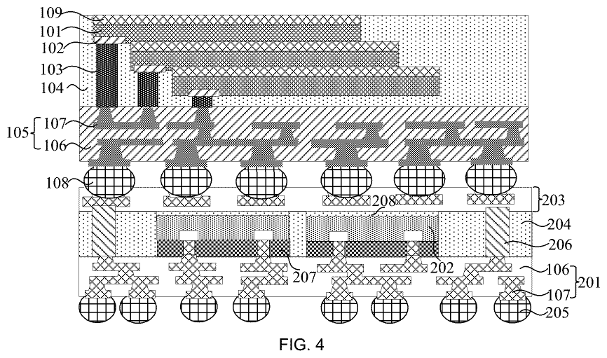

As shown in FIGS. 1-4, structures forming a POP structure for a three-dimensional fan-out memory device are disclosed. The structures include: a three-dimensional fan-out memory package unit 10 as shown in FIGS. 1-2, and a two-dimensional fan-out peripheral circuit chip SiP package unit 20 in FIG. 3, which is bonded to the three-dimensional fan-out memory package unit 10 to form the POP structure as shown in FIG. 4.

As shown in FIG. 2, the three-dimensional fan-out memory package unit 10 includes: at least two memory chips 101, although three memory chips are shown in the figures, laminated in a stepped configuration, each memory chip 101 being provided with a bonding pad 102 arranged on a step surface of the stepped configuration; first metal connection pillars 103, formed on and electrically connected to the bonding pads 102; a first encapsulating layer 104, which encapsulates the memory chips 101 and the first metal connection pillars 103, and a first surface of the first encapsulating layer 104 exposes the top surfaces of the first metal connection pillars 103; a first rewiring layer 105 having a first surface and a second surface, the second surface of the first rewiring layer 105 is formed on the first surface of the first encapsulating layer 104, and the first rewiring layer 105 is electrically connected to the top surfaces of the first metal connection pillars 103; and first metal bumps 108, formed on the first surface of the first rewiring layer 105.

As shown in FIG. 3, the two-dimensional fan-out peripheral circuit chip SiP package unit 20 includes: a second rewiring layer 201 having a first surface and a second surface; at least one peripheral circuit chip 202, although two such chips are shown in FIG. 3, arranged in two dimensions and electrically connected with the first surface of the second rewiring layer 201; a third rewiring layer 203 having a first surface and a second surface, the second surface of the third rewiring layer 203 is bonded to the peripheral circuit chip 202; second metal connection pillars 206, located away from the outside of the peripheral circuit chip 202, each of the second metal connection pillars 206 has one end electrically connected with the first surface of the second rewiring layer 201, and another end electrically connected with the second surface of the third rewiring layer 203; a second encapsulating layer 204, which encapsulates the peripheral circuit chip 202 and the second metal connection pillars 206; and second metal bumps 205, formed on the second surface of the second rewiring layer 201.

As shown in FIG. 4, the first metal bumps 108 are bonded to the first surface of the third rewiring layer 203 to achieve bonding between the three-dimensional fan-out memory package unit 10 and the two-dimensional fan-out peripheral circuit chip SiP package unit 20, to form the integrated POP structure.

The POP structure of the three-dimensional fan-out memory provided in this Embodiment adopts a fan-out pattern and realizes a package-on-package (POP) structure by rewiring layers in which a three-dimensional fan-out memory package unit and a two-dimensional fan-out peripheral circuit chip SiP package unit are connected, thereby obtaining a memory-encapsulated POP structure. In addition, the first metal connection pillars enables the leadout of the memory chip circuit, and through-silicon-via (TSV) holes are not required in the entire package structure for any circuit lead-out, which effectively reduces packaging costs. This eliminates the circuit substrate required for traditional electronic component packaging, enables high-density and high-integration device packaging, and achieves the minimum line width/line spacing reduction to 1.5 μm/1.5 μm. As a result, the process time will be shortened, and efficiency will be increased. Further, the overall thickness dimension of the package structure will be significantly reduced. Finally, this POP structure makes it possible to realize a one-stop packaging process in which a substrate is used to support the back-end-of-line (BEOL) instead of the middle-end-of-line (MEOL).

The memory chip 101 can be any memory chip suitable for three-dimensional lamination, such as DRAM, SRAM, flash memory, EEPROM, PRAM, MRAM and RPAM. In addition, the functions of the memory chips 101 in each layer of the laminated memory chips in the stepped configuration may be the same or different, the sizes of the memory chips 101 in each layer may be the same or different, and the sizes of the step surface of the memory chips 101 in each layer can be the same or different. The above parameters may be set according to the specific requirements of the package structure. The peripheral circuit chip 202 is mainly used to drive and control the memory chip 101. The peripheral circuit chip 202 may include peripheral circuit transistors and peripheral logic circuits. The peripheral logic circuits may include, but are not limited to, static random access memory (SRAM), phase locked loop (PLL), central processing unit (CPU), field programmable gate array (FPGA), etc. The design of the peripheral logic circuits depends on the different chips and functions.

As shown in FIG. 4, the first metal connection pillar 103 serves as an electrical connection conduit between the bonding pad 102 and the first rewiring layer 105, to lead out the signal of the memory chip 101; the second metal connection pillar 206 serves as an electrical connection conduit between the second rewiring layer 201 and the third rewiring layer 203, to lead out the signal of the peripheral circuit chip 202. The materials of the first metal connection pillar 103 and the second metal connection pillar 206 may have good conductivity and do not cause outward diffusion. For example, the material of the first metal connection pillar 103 is selected from gold, silver, aluminum, and copper, and the material of the second metal connection pillar 260 is selected from gold, silver, aluminum, and copper. However, the material of the first metal connection pillar 103 and the second metal connection pillar 206 is not limited to the above-mentioned, other materials having good conductivity are also applicable.

As shown in FIGS. 1 and 2, the material of the bonding pad 102 on each memory chip 101 includes metallic aluminum, i.e., the bonding pad 102 is an aluminum bonding pad. When preparing the bonding pad 102, an adhesive layer may be formed under the bonding pad 102, and an anti-reflection layer may be formed on the bonding pad 102, in order to improve electrical properties of the bonding pad and enhance the bonding between the bonding pad and the memory chip 101.

As shown in FIG. 4, as an example, the material of the first encapsulating layer 104 includes one of polyimide, silicone, and epoxy resin; similarly, the material of the second encapsulating layer 204 includes one of polyimide, silicone, and epoxy resin. Top surfaces of the first encapsulating layer 104 and the second encapsulating layer 204 are both ground or polished flat surfaces, to improve the quality of the subsequently formed rewiring layers and the quality of the package body.

As shown in FIGS. 1-4, the first rewiring layer 105, the second rewiring layer 201, and the third rewiring layer 203 each includes a dielectric layer 106 and a metal wiring layer 107. The material of the dielectric layer 106 includes one or a combination of two or more of epoxy resin, silicone rubber, polyimide (PI), polybenzoxazole (PBO), benzocyclobutene (BCB), silicon oxide, phosphorosilicate glass, and fluorine-containing glass. The material of the metal wiring layer 107 includes one or a combination of two or more of copper, aluminum, nickel, gold, silver, and titanium. It should be noted here that although the first rewiring layer 105, the second rewiring layer 201, and the third rewiring layer 203 each includes a dielectric layer 106 and a metal wiring layer 107, the material, number of layers and distribution shape of the rewiring layers at different locations will be set according to actual needs and are not limited herein.

As shown in FIGS. 1-4, one of the first metal bumps 108 or one of the second metal bumps 205 includes a connecting structure, which includes a solder ball, or a metal pillar and a solder ball formed on the metal pillar. Preferably, the solder ball includes one of a gold-tin solder ball, a silver-tin solder ball, and a copper-tin solder ball. Preferably, the metal pillar is a copper pillar or a nickel pillar. In this embodiment, the first metal bumps 108 and the second metal bumps 205 are in the form of gold-tin solder balls, the manufacturing steps of which include: first forming a gold-tin layer, then using a high-temperature reflow process to reflow the gold-tin layer into a ball, and then forming a gold-tin solder ball after cooling down; or using a bumping process to form a gold-tin solder ball.

### Embodiment 2

This embodiment provides a method of packaging a POP structure of a three-dimensional fan-out memory. The POP structure of the three-dimensional fan-out memory of Embodiment 1 can be prepared using the packaging method of this embodiment. However, the POP structure of the three-dimensional fan-out memory of Embodiment 1 can also be prepared using other packaging methods.

Specifically, FIGS. 1-4 show schematic diagrams of the structures presented in each step of the packaging method of the POP structure of the three-dimensional fan-out memory according to this embodiment.

As shown in FIGS. 1-3, step S1 is first performed to provide a three-dimensional fan-out memory package unit 10 and a two-dimensional fan-out peripheral circuit chip SiP package unit 20. As shown in FIG. 2, the three-dimensional fan-out memory package unit 10 includes: at least two memory chips 101, although there are three memory chips in the figures, laminated in a stepped configuration, each memory chip 101 being provided with a bonding pad 102 arranged on a step surface of the stepped configuration; first metal connection pillars 103, forming on and electrically connected to the bonding pads 102; a first encapsulating layer 104, which encapsulates the memory chips 101 and the first metal connection pillars 103, and a first surface of the first encapsulating layer 104 exposes the top surfaces of the first metal connection pillars 103; a first rewiring layer 105 having a first surface and a second surface, the second surface of the first rewiring layer 105 is formed on the first surface of the first encapsulating layer 104, and the first rewiring layer 105 is electrically connected to the first metal connection pillars 103; and first metal bumps 108, formed on the first surface of the first rewiring layer 105. As shown in FIG. 3, the two-dimensional fan-out peripheral circuit chip SiP package unit 20 includes: a second rewiring layer 201 having a first surface and a second surface; at least one peripheral circuit chip 202, although two such chips are shown in FIG. 3, arranged in two dimensions and electrically connected with the first surface of the second rewiring layer 201; a third rewiring layer 203 having a first surface and a second surface, the second surface of the third rewiring layer 203 is bonded to the peripheral circuit chip 202; second metal connection pillars 206, located away from the outside of the peripheral circuit chip 202, each of the second metal connection pillars 206 has one end electrically connected with the first surface of the second rewiring layer 201, and another end electrically connected with the second surface of the third rewiring layer 203; a second encapsulating layer 204, which encapsulates the peripheral circuit chip 202 and the second metal connection pillars 206; and second metal bumps 205, formed on the second surface of the second rewiring layer 201.

As shown in FIGS. 1-2, as a specific example, the method of forming the three-dimensional fan-out memory package unit 10 includes steps S11-S15.

S11, as shown in FIG. 1, includes providing at least two memory chips 101 each having the solder pad 102, and laminating the memory chips 101 in a stepped configuration. Specifically, a support substrate may be provided and a separation layer may be formed on the support substrate, and then the memory chips 101 may be laminated and bonded to the separation layer. Preferably, the memory chips 101 may be laminated and bonded to the separation layer using a surface mount process, and the bonding between two adjacent memory chips 101 and between the memory chip 101 and the separation layer is achieved by a first bonding layer 109.

S12, as shown in FIG. 1, includes forming the first metal connection pillars 103 on the bonding pads 102, respectively. The first metal connection pillars 103 may be formed by electroplating or chemical plating.

S13, as shown in FIG. 1, includes encapsulating the memory chips 101 and the first metal connection pillars 103 by the first encapsulating layer 104, and the top surfaces of the first metal connection pillars 103 is exposed from a top surface of the first encapsulating layer 104. The first encapsulating layer 104 may be formed by the method of compression molding, transfer molding, hydraulic molding, vacuum lamination or spin coating. Preferably, after forming the first encapsulating layer 104, a process of grinding or polishing may also be applied to the upper surface of the first encapsulating layer 104, to provide a first encapsulating layer 104 with a flat surface and to improve product quality.

S14, as shown in FIG. 2, includes forming the first rewiring layer 105 on a first surface of the first encapsulating layer 104. The first metal connection pillars 103 are electrically connected to the first rewiring layer 105. As a specific example, the forming of the first rewiring layer 105 may include the following steps: first forming a dielectric layer using a chemical vapor deposition process or a physical vapor deposition process, and etching the dielectric layer to form a patterned dielectric layer 106; then forming a metal wiring layer on a surface of the patterned dielectric layer 106 using a chemical vapor deposition process, a physical vapor deposition process, a sputtering process, an electroplating process, or a chemical plating process, and etching the metal wiring layer to form a patterned metal wiring layer 107. It should be noted here that the material, number of layers and distribution shape of the dielectric layer 106 and the metal wiring layer 107 can be set according to the specific conditions of different memory chips and will not be limited here.

S15, as shown in FIG. 2, includes forming the first metal bumps 108 on the first surface of the first rewiring layer 105. As an example, one of the first metal bumps 108 includes a connecting structure, which includes a solder ball, or a metal pillar and a solder ball formed on the metal pillar. Preferably, the solder ball includes one of a gold-tin solder ball, a silver-tin solder ball, and a copper-tin solder ball. Preferably, the metal pillar is a copper pillar or a nickel pillar. In this embodiment, the first metal bumps 108 are gold-tin solder balls, the manufacturing steps of which include: first forming a gold-tin layer on the surface of the first rewiring layer 105, then using a high-temperature reflow process to reflow the gold-tin layer into a ball, and then forming a gold-tin solder ball after cooling down; or using a bumping process to form a gold-tin solder ball. It should be noted here that after forming the first metal bumps 108, the separation layer and the support substrate are removed to obtain the three-dimensional fan-out memory package unit 10.

As shown in FIG. 3, as a specific example, the method of forming the two-dimensional fan-out peripheral circuit chip SiP package unit 20 includes: forming the second rewiring layer 201 having the first surface and the second surface; electrically connecting at least one peripheral circuit chip 202 arranged in two dimensions to the first surface of the second rewiring layer 201; electrically connecting one end of each of the second metal connection pillars 206 to the first surface of the second rewiring layer 201, where the second metal connection pillars 206 are located away from the outside of the peripheral circuit chip 202; encapsulating the peripheral circuit chip 202 and the second metal connection pillars 206 using the second encapsulating layer 204; after forming the second encapsulating layer 204, a process of grinding or polishing may be applied to the upper surface of the second encapsulating layer 204, to provide a second encapsulating layer 204 with a flat surface and to improve product quality; forming the third rewiring layer 203 having the first surface and the second surface on the peripheral circuit chip 202 and the second metal connection pillars 206, where the second surface of the third rewiring layer 203 is bonded to the peripheral circuit chip 202, and another end of each of the second metal connection pillars 206 is electrically connected with the second surface of the third rewiring layer 203; and forming the second metal bumps 205 on the second surface of the second rewiring layer 201. A bottom filler layer 207 may be provided between the peripheral circuit chip 202 and the first surface of the second rewiring layer 201, to improve the bond strength between the two and to protect the second rewiring layer 201. The peripheral circuit chip 202 may be bonded to the second surface of the third rewiring layer 203 by a second bonding layer 208.

As an example, the method of forming the second rewiring layer 201 and the third rewiring layer 203 can be referred to the method of forming the first rewiring layer 105 above and will not be repeated herein.

As shown in FIG. 4, step S2 is then performed to bond the first metal bumps 108 to the first surface of the third rewiring layer 203 to achieve bonding of the three-dimensional fan-out memory package unit 10 to the two-dimensional fan-out peripheral circuit chip SiP package unit 20, so as to obtain the POP structure of the three-dimensional fan-out memory of the present disclosure.

As mentioned above, the POP structure of the three-dimensional fan-out memory provided by the present disclosure adopts a fan-out pattern and realizes a package-on-package (POP) structure by multiple rewiring layers in which a three-dimensional fan-out memory package unit and a two-dimensional fan-out peripheral circuit chip SiP package unit are interconnected, thereby obtaining a memory-encapsulated POP structure. In addition, the first metal connection pillars enables the leadout of the memory chip circuit, and TSV holes are not required in the entire package structure for any circuit lead-out, which effectively reduces packaging costs. This eliminates the circuit substrate required for traditional electronic component packaging, enables high-density and high-integration device packaging, and achieves the minimum line width/line spacing reduction to 1.5 μm/1.5 μm. As a result, the process time will be shortened, and efficiency will be increased. Further, the overall thickness dimension of the package structure will be significantly reduced. Finally, this POP structure makes it possible to realize a one-stop packaging process in which a substrate is used to support the back-end-of-line (BEOL) instead of the middle-end-of-line (MEOL). Therefore, the present disclosure effectively overcomes various shortcomings in the existing technology and has high industrial utilization value.

The above-mentioned embodiments are merely illustrative of the principle and effects of the present disclosure instead of limiting the present disclosure. Modifications or variations of the above-described embodiments may be made by those skilled in the art without departing from the spirit and scope of the disclosure. Therefore, all equivalent modifications or changes made by those who have common knowledge in the art without departing from the spirit and technical concept disclosed by the present disclosure shall be still covered by the claims of the present disclosure.

What is claimed is:

1. A package-on-package (POP) structure, comprising:
a first package unit, wherein the first package unit comprises a three-dimensional fan-out memory device; and
a system-in-package (SiP) package unit, wherein the SIP package unit comprises a two-dimensional fan-out peripheral circuit;
wherein the first package unit and the SiP package unit are bonded together;
wherein the three-dimensional fan-out memory device comprises:
at least two memory chips laminated in a stepped configuration, wherein each of the at least two memory chips is provided with one of bonding pads arranged on one step surface of the stepped configuration;
first metal connection pillars, wherein each of the first metal connection pillars is formed on and electrically connected to one of the bonding pads;
a first encapsulating layer, which encapsulates the at least two memory chips and the first metal connection pillars, wherein top surfaces of the first metal connection pillars are exposed from a first surface of the first encapsulating layer;
a first rewiring layer having a first surface and a second surface, wherein the second surface of the first rewiring layer is formed on the first surface of the first encapsulating layer, wherein the first rewiring layer is electrically connected to the first metal connection pillars; and
first metal bumps, formed on the first surface of the first rewiring layer;
wherein the two-dimensional fan-out peripheral circuit comprises:
a second rewiring layer having a first surface and a second surface;
at least one peripheral circuit chip, arranged in two dimensions and electrically connected with the first surface of the second rewiring layer;
a third rewiring layer having a first surface and a second surface, wherein the second surface of the third rewiring layer is bonded to the at least one peripheral circuit chip;
second metal connection pillars, disposed outside of the at least one peripheral circuit chip, wherein each of the second metal connection pillars has one end electrically connected with the first surface of the second rewiring layer, and another end electrically connected with the second surface of the third rewiring layer;
a second encapsulating layer, encapsulating the at least one peripheral circuit chip and the second metal connection pillars, wherein top surfaces of the second metal connection pillars are exposed from a top surface of the second encapsulating layer; and
second metal bumps, formed on the second surface of the second rewiring layer;
wherein the first metal bumps are bonded to the first surface of the third rewiring layer to achieve attachment between the first package unit of the three-dimensional fan-out memory device and the SiP package unit of the two-dimensional fan-out peripheral circuit.

2. The POP structure according to claim 1, wherein a material of the first metal connection pillars comprises at least one of gold, silver, aluminum, and copper; and wherein a material of the second metal connection pillars comprises at least one of gold, silver, aluminum, and copper.

3. The POP structure according to claim 1, wherein a material of the bonding pad comprises metallic aluminum, a material of the first encapsulating layer comprises one of polyimide, silicone, and epoxy resin, and a material of the second encapsulating layer comprises one of polyimide, silicone, and epoxy resin.

4. The POP structure according to claim 1, wherein each of the first rewiring layer, the second rewiring layer, and the third rewiring layer comprises a dielectric layer and a metal wiring layer; wherein a material of the dielectric layer comprises one or a combination of two or more of epoxy resin, silicone, polyimide (PI), polybenzoxazole (PBO), benzocyclobutene (BCB), silicon oxide, phosphorosilicate glass, and fluorine-containing glass, and a material of the metal wiring layer comprises one or a combination of two or more of copper, aluminum, nickel, gold, silver, and titanium.

5. The POP structure according to claim 1, wherein one of the first metal bumps or one of the second metal bumps comprises a connecting structure, which includes a solder ball, or a metal pillar, or a solder ball formed on the metal pillar, wherein the solder ball comprises one of a gold-tin solder ball, a silver-tin solder ball, and a copper-tin solder ball.

6. A method of packaging a package-on-package (POP) structure, comprising:
forming a first package unit comprising a three-dimensional fan-out memory device; and forming a system-in-package (SiP) package unit comprising a two-dimensional fan-out peripheral circuit;
wherein forming the first package unit of the three-dimensional fan-out memory device comprises:
providing at least two memory chips laminated in a stepped configuration, wherein each of the at least two memory chips is provided with one of bonding pads arranged on one of step surfaces of the stepped configuration;
forming first metal connection pillars, wherein each of the first metal connection pillars is disposed on and electrically connected to one of the bonding pads;
forming a first encapsulating layer, wherein the first encapsulating layer encapsulates the at least two memory chips and the first metal connection pillars, wherein top surfaces of the first metal connection pillars are exposed from a first surface of the first encapsulating layer;
forming a first rewiring layer having a first surface and a second surface, wherein the second surface of the first rewiring layer is formed on the first surface of the first encapsulating layer, and wherein the first rewiring layer is electrically connected to the first metal connection pillars; and
forming first metal bumps on the first surface of the first rewiring layer;
wherein forming the SiP package unit of the two-dimensional fan-out peripheral circuit comprises:
forming a second rewiring layer having a first surface and a second surface;
providing at least one peripheral circuit chip, wherein the at least one peripheral circuit chip is arranged in two dimensions and electrically connected with the first surface of the second rewiring layer;
forming a third rewiring layer having a first surface and a second surface, wherein the second surface of the third rewiring layer is bonded to the at least one peripheral circuit chip;
forming second metal connection pillars, wherein the second metal connection pillars are disposed outside of the at least one peripheral circuit chip, wherein each of the second metal connection pillars has one end electrically connected with the first surface of the second rewiring layer, and another end electrically connected with the second surface of the third rewiring layer;
forming a second encapsulating layer, wherein the second encapsulating layer encapsulates the at least one peripheral circuit chip and the second metal connection pillars, wherein top surfaces of the second metal connection pillars are exposed from the second encapsulating layer; and
forming second metal bumps, wherein the second metal bumps are disposed on the second surface of the second rewiring layer; and
bonding the first metal bumps to the first surface of the third rewiring layer, to achieve attachment between the first package unit of the three-dimensional fan-out memory device and the SiP package unit of the two-dimensional fan-out peripheral circuit.

7. The method of packaging the POP structure according to claim 6, wherein forming the first package unit of the three-dimensional fan-out memory device comprises:
providing at least two memory chips each having one of the bonding pads, and laminating the at least two memory chips in the stepped configuration;
forming the first metal connection pillars on the bonding pads, respectively;
encapsulating the at least two memory chips and the first metal connection pillars by the first encapsulating layer, exposing top surfaces of the first metal connection pillars from the first surface of the first encapsulating layer;
forming the first rewiring layer on the first surface of the first encapsulating layer, wherein the first metal connection pillars are electrically connected to the first rewiring layer; and
forming the first metal bumps on the first surface of the first rewiring layer.

8. The method of packaging the POP structure according to claim 7, wherein the laminating of the at least two memory chips is realized by a surface mount process.

9. The method of packaging the POP structure according to claim 6, wherein forming the SiP package unit of the two-dimensional fan-out peripheral circuit comprises:
forming the second rewiring layer having the first surface and the second surface;
electrically connecting the at least one peripheral circuit chip to the first surface of the second rewiring layer;
electrically connecting the second metal connection pillars to the first surface of the second rewiring layer, wherein the second metal connection pillars are formed outside of the at least one peripheral circuit chip;
encapsulating the at least one peripheral circuit chip and the second metal connection pillars using the second encapsulating layer;
forming the third rewiring layer on the at least one peripheral circuit chip and the second metal connection pillars, wherein the third rewiring layer is bonded to the at least one peripheral circuit chip, and the second metal connection pillars are electrically connected with the second surface of the third rewiring layer; and
forming the second metal bumps on the second surface of the second rewiring layer.

10. The method of packaging the POP structure according to claim 6, further comprising polishing the top surfaces of the first encapsulating layer and the second encapsulating layer after forming the first encapsulating layer and the second encapsulating layer.
